(19) United States
(12) Patent Application Publication
(10) Pub. No.: US 2025/0002699 A1
(43) Pub. Date: Jan. 2, 2025

(54) CROSSLINKABLE POLYOLEFIN COMPOSITION

(71) Applicant: SABIC GLOBAL TECHNOLOGIES B.V., BERGEN OP ZOOM (NL)

(72) Inventors: Hongmei ZHOU, Shanghai (CN); Kai GUO, Shanghai (CN); Hao LIU, Shanghai (CN); You Jun WU, Shanghai (CN); Pei SUN, Shanghai (CN); Xiaofeng YU, Shanghai (CN)

(21) Appl. No.: 18/706,120

(22) PCT Filed: Nov. 2, 2022
(86) PCT No.: PCT/EP2022/080547

§ 371 Date: Apr. 30, 2024

(30) Foreign Application Priority Data
Nov. 3, 2021 (WO) PCT/CN2021/128443
Dec. 17, 2021 (EP) 21215668.1

(51) Int. Cl. C08L 23/08; B29C 48/00; B29C 48/08; B29C 48/36; B29K 23/00; B29L 31/34; C08K 5/14; H01L 31/048

(52) U.S. Cl. CPC C08L 23/0815; B29C 48/022; B29C 48/08; B29C 48/36; C08K 5/14; H01L 31/0481; B29K 2023/16; B29K 2995/0003; B29K 2995/0012; B29K 2995/0063; B29K 2995/007; B29K 2995/0077; B29L 2031/34; C08L 2203/204

(57) ABSTRACT

A crosslinkable polyolefin composition includes: a) ≥60.0 wt. % and ≤99.0 wt. % of an ethylene alpha-olefin co-polymer; b) ≥1.0 wt. % and ≤35.0 wt. % of an ethylene-alpha-olefin-diene terpolymer; c) ≥0.1 wt. % and ≤5.0 wt. % of a crosslinking agent; with regard to the total weight of the polyolefin composition. A film includes the polyolefin composition. An encapsulated solar cell is encapsulated by at least two sealing layers each including such a film. In addition, a cured solar cell is obtained by subjecting the encapsulated solar cell under conditions of curing the sealing layers, a photovoltaic module includes the cured solar cell.

### CROSS REFERENCE TO RELATED APPLICATIONS

This application is a National Stage application of PCT/EP2022/080547, filed Nov. 2, 2022, which claims the benefit of PCT/CN2021/128443, filed Nov. 3, 2021, and European Application 21215668.1, filed Dec. 17, 2021, all of which are incorporated by reference in their entirety herein.

### BACKGROUND

The invention relates to crosslinkable polyethylene compositions, a process for preparing such polyethylene compositions and to the use of such polyethylene compositions for manufacturing encapsulants suitable for photovoltaic modules. The invention further relates to a film comprising the polyethylene composition and to an encapsulated solar cell, encapsulated by at least two sealing layers each comprising the film. In addition, the invention is further directed to a cured solar cell obtained by subjecting the encapsulated solar cell under conditions sufficient to cure the sealing layers and to a photovoltaic module comprising the cured solar cell.

Polymeric materials such as ethylene-vinyl acetate copolymers (EVA) and polyolefin elastomers (POE), are commonly used as encapsulants in photovoltaic modules and other similar electronic device such as liquid crystal panels, electro-luminescent devices and plasma display units. Some desirable properties of such polymeric materials intended for photovoltaic modules include (i) protecting the module from exposure to external environment, e.g., moisture and air, (ii) protecting the module against mechanical shock, (iii) ease of processing, (iv) short cure times with protection of the module from mechanical stress resulting from polymer shrinkage during cure, (v) high electrical resistance (volume resistivity), and (vi) high thermal creep resistance.

A possible way of increasing thermal creep resistance, is by subjecting the polymeric material to conditions of crosslinking in presence of organic peroxide initiators. Further, for photovoltaic manufacturing industry, using polymeric encapsulant materials which are crosslinkable results in shortened curing time and improved manufacturing efficiency. Although crosslinking of the polymeric material addresses in part the issue of thermal creep, it may give rise to other issues such as 1) material corrosion, induced by the presence of residual peroxides post the crosslinking treatment, or 2) adverse processability due to premature crosslinking of the polymeric material.

Polymeric material such as ethylene-vinyl acetate copolymers (EVA) and polyolefin elastomers (POE) have been used for preparing polymeric encapsulants suitable for photovoltaic and other allied applications. However, EVA copolymers, owing to their polarity, suffer from having low volume resistivity and low moisture barrier properties, as compared to polyolefin elastomers. Further, it has been observed that EVA based films progressively darken on exposure to sunlight due to chemical degradation, which in turn may cause loss in power output. In addition, EVA resins tend to absorb moisture when exposed to atmosphere and are therefore prone to degradation.

On the other hand, polyolefin elastomers (POE) have low crosslinking rate, thereby limiting their commercial application as encapsulants. In the past, several encapsulant manufacturers and converters have attempted to address the issue of low crosslinking rate of polyolefin elastomers by developing materials based on co-extrusion of EVA-POE polymers, with the thought of obtaining materials, which would have the best of properties from both EVA copolymers and polyolefin elastomers. However, such materials, although promising, do not completely address all the combined drawbacks of EVA and polyolefin elastomers (POE), as it has been observed by industry practitioners, that the desired balance of properties such as the balance of volume resistivity and crosslinking rate, as desired for an encapsulant material, was not achieved.

### SUMMARY

Therefore, it is an object of the present invention to provide a polyolefin composition, which can be suitably used in the manufacturing of photovoltaic module encapsulants having one or more of the following advantages of (i) low curing time, (ii) high volume resistivity, and (iii) improved processability.

Accordingly, one or more objectives of the present invention is achieved by a polyolefin composition, comprising:
a) ≥60.0 wt. % and ≤99.0 wt. % of an ethylene alpha-olefin co-polymer, with regard to the total weight of the polyolefin composition, wherein the ethylene alpha-olefin co-polymer has at least one of:
   i. a peak melting temperature of ≥60° C. and ≤90° C., preferably ≥65° C. and ≤75° C., when determined in accordance with ASTM D3418-15, using Differential Scanning calorimetry (DSC) with a first heating and cooling cycle at a temperature between 23° C. to 200° C. and at a heating and a cooling rate of 10° C./min for a 10 mg film sample, using a nitrogen purge gas at flow rate of 50±5 mL/min, followed by a second heating cycle identical to the first heating cycle;
   ii. ≥20.0 wt. % and ≤45.0 wt. %, preferably ≥28.0 wt. % and ≤40.0 wt. %, preferably ≥30.0 wt. % and ≤40.0 wt. %, of polymeric units derived from one or more alpha-olefins having 3-12 carbon atoms, with regard to the total weight of the ethylene alpha-olefin co-polymer;
   iii. a vinyl unsaturation of ≥6.0 per 10⁵ carbon atoms, preferably ≥7.0 per 10⁵ carbon atoms, preferably ≥12.0 per 10⁵ carbon atoms, when determined in accordance with ASTM D6248-98 (2012);
b) ≥1.0 wt. % and ≤35.0 wt. % of an ethylene-alpha-olefin-diene terpolymer, with regard to the total weight of the polyolefin composition, wherein the ethylene-alpha-olefin-diene terpolymer comprises a total vinyl and vinylidene unsaturation of ≥20.0 and ≤100.0 per 10⁵ carbon atoms, preferably ≥30.0 and ≤80.0 per 10⁵ carbon atoms, when determined in accordance with ASTM D6248-98 (2012); and
c) ≥0.1 wt. % and ≤5.0 wt. % of a crosslinking agent, with regard to the total weight of the polyolefin composition.

### DETAILED DESCRIPTION

Preferably, the invention relates to a polyolefin composition, comprising:
a) ≥60.0 wt. % and ≤99.0 wt. % of an ethylene alpha-olefin co-polymer, with regard to the total weight of the polyolefin composition, preferably wherein the ethylene alpha-olefin co-polymer comprises polymeric units derived from ethylene and one or more alpha-olefin selected from 1-butene, 1-hexene, 4-methyl-1-pentene, 1-octene, or combinations thereof, preferably the alpha-olefin is selected from 1-butene or 1-octene, further wherein the ethylene alpha-olefin co-polymer has at least one of:
   i. a peak melting temperature of ≥60° C. and ≤90° C., preferably ≥65° C. and ≤75° C., when determined in accordance with ASTM D3418-15, using Differential Scanning calorimetry (DSC) with a first heating and cooling cycle at a temperature between 23° C. to 200° C. and at a heating and a cooling rate of 10° C./min for a 10 mg film sample, using a nitrogen purge gas at flow rate of 50±5 mL/min, followed by a second heating cycle identical to the first heating cycle;
   ii. ≥20.0 wt. % and ≤45.0 wt. %, preferably ≥28.0 wt. % and ≤40.0 wt. %, preferably ≥30.0 wt. % and ≤40.0 wt. %, of polymeric units derived from one or more alpha-olefins having 3-12 carbon atoms, with regard to the total weight of the ethylene alpha-olefin co-polymer;
   iii. a vinyl unsaturation of ≥6.0 per 10⁵ carbon atoms, preferably ≥7.0 per 10⁵ carbon atoms, preferably ≥12.0 per 10⁵ carbon atoms, when determined in accordance with ASTM D6248-98 (2012);

b) ≥1.0 wt. % and ≤35.0 wt. % of an ethylene-alpha-olefin-diene terpolymer, with regard to the total weight of the polyolefin composition, wherein the ethylene-alpha-olefin-diene terpolymer comprises a total vinyl and vinylidene unsaturation of ≥20.0 and ≤100.0 per 10⁵ carbon atoms, preferably ≥30.0 and ≤80.0 per 10⁵ carbon atoms, when determined in accordance with ASTM D6248-98 (2012); and
c) ≥0.1 wt. % and ≤5.0 wt. % of a crosslinking agent, with regard to the total weight of the polyolefin composition.

The ethylene alpha-olefin co-polymer may be so selected to have a suitable melt flow rate and density. Preferably the ethylene alpha-olefin co-polymer may have at least one of:
a) a melt flow rate (MFR) of ≥5.0 g/10 min and ≤25.0 g/10 min, preferably ≥10.0 g/10 min and ≤20.0 g/10 min, preferably ≥11.0 g/10 min and ≤15.0 g/10 min, when determined at 190° C. at 2.16 kg load in accordance with ASTM D1238 (2013); and/or
b) a density of ≥850 kg/m³ and ≤900 kg/m³, preferably ≥870 kg/m³ and ≤880 kg/m³, when determined in accordance with ASTM D792 (2008).

The ethylene alpha-olefin co-polymer may for example contain a suitable amount of chain end unsaturation expressed as the amount of vinyl unsaturation per 10⁵ carbon atoms. Without being bound by any specific theory, it is believed that for the ethylene alpha-olefin co-polymer, the vinyl unsaturation content influences the rate of crosslinking and therefore the amount of vinyl unsaturation content should desirably be present above a certain limit in order to promote crosslinking. On the other hand it is believed that, for the ethylene alpha-olefin co-polymer, the vinylidene unsaturation content has limited influence in promoting crosslinking. Therefore, the type of unsaturation content (e.g. vinyl or vinylidene) will play a role in the selection of a suitable ethylene alpha-olefin co-polymer for improving crosslinking.

Preferably, the ethylene alpha-olefin co-polymer has a vinyl unsaturation of ≥6.0 per 10⁵ carbon atoms, preferably ≥7.0 per 10⁵ carbon atoms, preferably ≥12.0 per 10⁵ carbon atoms, when determined in accordance with ASTM D6248-98 (2012). Preferably, the ethylene alpha-olefin co-polymer has a vinyl unsaturation of ≥6.0 and ≤25.0, preferably ≥10.0 and ≤20.0 per 10⁵ carbon atoms, when determined in accordance with ASTM D6248-98 (2012).

Preferably the ethylene alpha-olefin co-polymer has:
a) a peak melting temperature of ≥60° C. and ≤90° C., preferably ≥65° C. and ≤75° C., when determined in accordance with ASTM D3418-15, using Differential Scanning calorimetry (DSC) with a first heating and cooling cycle at a temperature between 23° C. to 200° C. and at a heating and a cooling rate of 10° C./min for a 10 mg film sample, using a nitrogen purge gas at flow rate of 50±5 mL/min, followed by a second heating cycle identical to the first heating cycle; and/or
b) ≥20.0 wt. % and ≤45.0 wt. %, preferably ≥28.0 wt. % and ≤40.0 wt. %, preferably ≥ 30.0 wt. % and ≤40.0 wt. %, of polymeric units derived from one or more alpha-olefins having 3-12 carbon atoms, with regard to the total weight of the ethylene alpha-olefin co-polymer; and/or
c) a vinyl unsaturation of ≥6.0 per 10⁵ carbon atoms, preferably ≥7.0 per 10⁵ carbon atoms, preferably ≥12.0 per 10⁵ carbon atoms, when determined using in accordance with ASTM D6248-98 (2012);
d) a melt flow rate (MFR) of ≥5.0 g/10 min and ≤25.0 g/10 min, preferably ≥10.0 g/10 min and ≤20.0 g/10 min, preferably ≥11.0 g/10 min and ≤15.0 g/10 min, when determined at 190° C. at 2.16 kg load in accordance with ASTM D1238 (2013); and/or
e) a density of ≥850 kg/m³ and ≤900 kg/m³, preferably ≥870 kg/m³ and ≤880 kg/m³, when determined in accordance with ASTM D792 (2008).

Preferably, the peak melting temperature of the ethylene alpha-olefin co-polymer may be of ≥70° C. and ≤75° C., when determined in accordance with ASTM D3418-15, using Differential Scanning calorimetry (DSC) with a first heating and cooling cycle at a temperature between 23° C. to 200° C. and at a heating and a cooling rate of 10° C./min for a 10 mg film sample, using a nitrogen purge gas at flow rate of 50±5 mL/min, followed by a second heating cycle identical to the first heating cycle. At this melting temperature, the resultant polyolefin composition may be processed effectively while retaining its thermal and creep stability.

The ethylene alpha-olefin co-polymer may for example comprise polymeric units derived from ethylene and one or more alpha-olefins selected from 1-butene, 1-hexene, 4-methyl-1-pentene, 1-octene, or combinations thereof. Preferably, the alpha-olefin is selected from 1-butene or 1-octene. In certain embodiments of the invention, the polymeric units derived from one or more alpha-olefins having 3-12 carbon atoms, may be present in a suitable amount in the ethylene alpha-olefin copolymer in order to impart the desired balance of crystalline and amorphous phase in the copolymer.

Preferably, the ethylene alpha-olefin co-polymer has ≥20.0 wt. % and ≤45.0 wt. %, preferably ≥28.0 wt. % and ≤40.0 wt. %, preferably ≥30.0 wt. % and ≤40.0 wt. %, preferably ≥35.0 wt. % and ≤40.0 wt. %, of polymeric units derived from one or more alpha-olefins having 3-12 carbon atoms, with regard to the total weight of the ethylene alpha-olefin co-polymer. The polymeric units derived from ethylene and the alpha-olefin may for example be determined via 13C NMR spectrometry according to the method presented in JAPS, Vol. 42, pp. 399-408, 1991.

The polyolefin composition comprises an ethylene-alpha-olefin-diene terpolymer having a certain content of end chain unsaturation expressed as the total amount of vinyl and vinylidene unsaturation per 10⁵ carbon atoms. Without being bound by any specific theory, it is believed that the total amount of vinyl and vinylidene unsaturation should be above a certain limit as both vinyl and vinylidene unsaturation contribute to promoting crosslinking reaction in terpolymers. Preferably, the ethylene-alpha-olefin-diene terpolymer comprises a total vinyl and vinylidene unsaturation of ≥20.0 and ≤100.0, preferably ≥30.0 and ≤80.0, preferably ≥35.0 and ≤50.0, per 10⁵ carbon atoms, when determined in accordance with ASTM D6248-98 (2012).

Preferably, the ethylene-alpha-olefin-diene terpolymer comprises a vinylidene unsaturation of ≥5.0 and ≤50.0, preferably ≥25.0 and ≤50.0, preferably ≥27.0 and ≤40.0, per 10⁵ carbon atoms, when determined in accordance with ASTM D6248-98. In some preferred embodiments of the invention, the content of unsaturation may be measured by ¹³C NMR on a Bruker Avance 500 spectrometer equipped with a cryogenically cooled probe head operating at 125° C., whereby the samples are dissolved at 130° C. in C₂D₂Cl₄ containing DBPC as stabilizer in accordance with ASTM D6248-98 (2012).

The ethylene-alpha-olefin-diene terpolymer comprises: 1) polymeric units derived from ethylene, 2) polymeric units derived from an alpha-olefin, and 3) polymeric units derived from a diene. For example, the ethylene-alpha-olefin-diene copolymer may comprise polymeric units derived from (i) ethylene; (ii) one or more alpha-olefins comprising 3-12 carbon atoms, preferably the one or more alpha olefin is selected from the group consisting of propylene, 1-butene, 1-hexene, 4-methyl-1-pentene, 1-octene; and (iii) a diene selected from the group consisting of 5-ethylidene-2-norbornene (ENB), 5-propylidene-5-norbornene, dicyclopentadiene (DCPD), 5-vinyl-2-norbornene, 5-methylene-2-norbornene, 5-isopropylidene-2-norbornene, norbornadiene, 1,4-hexadiene, 4-methyl-1,4-hexadiene, 5-methyl-1,4-hexadiene, 5-methyl-1,5-heptadiene, 6-methyl-1,5-heptadiene, 6-methyl-1,7-octadiene, 1,6-octadiene, 5-methyl-1,4-hexadiene, 3,7-dimethyl-1,6-octadiene, 2,5-norbornadiene and 7-methyl-1,6-octadiene. Preferably, the ethylene-alpha-olefin-diene terpolymer is ethylene-propylene-diene terpolymer. Preferably the ethylene-alpha-olefin-diene terpolymer is ethylene/propylene/5-ethylidene-2-norbornene terpolymer.

The ethylene-alpha-olefin-diene terpolymer has a suitable proportion of polymeric units derived from ethylene, alpha olefin monomers and a diene monomer. The ethylene-alpha-olefin-diene terpolymer may for example comprise:
a) ≥40.0 and ≤80.0 wt % of polymeric units derived from ethylene, when determined in accordance with ASTM D3900 (2015);
b) ≥20.0 and ≤50.0 wt % of polymeric units derived from alpha-olefin, preferably propylene, when determined in accordance with ASTM D3900 (2015); and
c) ≥0.1 and ≤15.0 wt % of polymeric units derived from a diene monomer, preferably the diene monomer is 5-ethylidene-2-norbornene (ENB), when determined in accordance with ASTM D6047 (99),
   with regard to the total weight of the ethylene-alpha-olefin-diene terpolymer.

The ethylene, alpha-olefin and diene monomers content of the terpolymer may for example be determined via ¹³C NMR spectrometry according to the method presented in JAPS, Vol. 42, pp. 399-408, 1991. The ethylene-alpha-olefin-diene terpolymer may for example have a Mooney viscosity ML (1+4) of ≥10.0 and ≤100.0 MU, preferably ≥20.0 and ≤80.0 MU, when determined in accordance with ASTM D1646. The ethylene-alpha-olefin-diene terpolymer may for example have a density of ≥850.0 kg/m³ and ≤910.0 kg/m³, preferably ≥870.0 kg/m³ and ≤900.0 kg/m³, when determined in accordance with ASTM D297-15 (2019).

In some embodiments of the invention, the polyolefin composition comprises a crosslinking agent. Preferably, the crosslinking agent is an organic peroxide selected from the group consisting of 2,5-dimethyl-2,5-di(t-butylperoxy)hexane, 3-di-t-butylperoxide, t-dicumylperoxide, 2,5-dimethyl-2,5-di(t-butylperoxy)hexyne, dicumylperoxide, α,α′-bis(t-butylperoxyisopropyl)benzene, 2,2-di(tert-butylperoxy)butane, n-butyl-4,4-bis(t-butylperoxy)butane, 1,1-bis(t-butylperoxy)cyclohexane, tertiarybutylperoxy-2-ethylhexyl carbonate, t-butylperoxybenzoate, 1,6-di(t-butylperoxycarbonyloxy)hexane, and combinations thereof. Preferably, the crosslinking agent is dicumylperoxide (DCP).

The crosslinking agent may be selected to have a suitable half-life time intended for use in an encapsulant. For example, if the half-life time of the organic peroxide at a particular temperature is too low, then the composition may be prematurely cross-linked thereby adversely affecting its processability during lamination or molding. On the other hand, if the half-life time of the organic peroxide is high, the overall processing efficiency is reduced during the lamination process or during the photovoltaic module production.

For example, the crosslinking agent may be an organic peroxide having a half-life time of ≥3.0 minutes and ≤85.0 minutes, preferably ≥10.0 minutes and ≤70.0 minutes, preferably ≥12.0 minutes and ≤25.0 minutes, when measured using the equation t_{0.5}=ln(2)/k, where t_{0.5} is the half life time and ‘k’ is the reaction rate constant determined using the Arrhenius Equation at a temperature of 140° C.

Preferably, the polyolefin composition may further comprise: ≥0.05 wt. % and ≤5.0 wt. %, of a coupling agent, preferably a silane coupling agent. The amount of silane coupling agent used in the practice of this invention may vary widely depending upon the nature of the ethylene-α-olefin copolymer, the type of silane used, processing conditions, grafting efficiency, intended application area, and similar such factors, but typically at least 0.05, preferably at least 0.5 wt % is used based on the total weight of the polyolefin composition.

Preferably, the coupling agent may be grafted to the ethylene alpha-olefin co-polymer. Suitable coupling agents include silane coupling agents. For example, any suitable silane coupling agent that will effectively graft and crosslink the ethylene alpha-olefin co-polymer may be used in the practice of this invention. Suitable silanes coupling agents include unsaturated silanes that comprise an ethylenically unsaturated hydrocarbyl group, such as a vinyl, allyl, isopropenyl, butenyl, cyclohexenyl or γ-(meth)acryloxy allyl group, and a hydrolyzable group, such as, for example, a hydrocarbyloxy, hydrocarbonyloxy, or hydrocarbylamino group. Non-limiting examples of hydrolyzable or polar groups include methoxy, acrylates, ethoxy, formyloxy, acetoxy, proprionyloxy, and alkyl or arylamino groups. Preferred silane coupling agents are the unsaturated alkoxy silanes, which may be grafted onto the ethylene alpha-olefin co-polymer.

These silanes and their methods of preparation are described in the patent, U.S. Pat. No. 5,266,627 and incorporated in this disclosure as a reference. Vinyl trimethoxy silane, vinyl triethoxy silane, γ-(meth)acryloxy propyl trimethoxy silane and mixtures of these silanes, are some of the preferred silane coupling agents suitable for use in accordance with this invention.

More preferably, the polyolefin composition comprises ≥0.05 wt. % and ≤5.0 wt. %, of a silane coupling agent, wherein the silane coupling agent is selected from vinyl trimethoxy silane, vinyl triethoxy silane, γ-(meth)acryloxy propyl trimethoxy silane, and combinations thereof. Alternatively, the silane coupling agents may be blended with the polyolefin composition and subsequently compounded using an extruder.

Preferably, the polyolefin composition may further comprise: ≥0.05 wt. % and ≤5.0 wt. % of one or more additives; with regard to the total weight of the polyolefin composition. The one or more additives may be selected from anti-oxidants, heat stabilizers, acid scavengers, release agents, plasticizers, hindered amine light stabilizer, antistatic additive, non-phenolic processing stabilizer, lubricants, scratch resistance agents, recycling additives, clarifying agent, processing stabilizers, antimicrobial agents, anti-fogging additives, slip additives, anti-blocking additives, non-phenolic processing stabilizer, or combinations thereof.

The polyolefin composition may further comprise a non-phenolic processing stabilizer. The non-phenolic processing stabilizer may for example be present in an amount of ≥0.05 wt. % and ≤5.0 wt. %, with regard to the total weight of the polyolefin composition. For example, the non-phenolic processing stabilizer comprises a mixture of hydroxylamine and a phosphite compound, preferably a 1:1 mixture of a hydroxylamine and a phosphite compound. Preferably, non-phenolic processing stabilizer is a 1:1 mixture of N,N-dioctadecylhydroxylamine (Irgastab® FS042) and a tris(2,4-di-tert-butylphenyl)phosphite (Irgafos® 168).

The polyolefin composition may further comprise a hindered amine light stabilizer. Preferably the hindered amine light stabilizer is poly[[6-[(1,1,3,3-tetramethylbutyl)amino]-1,3,5-triazine-2,4-diyl][(2,2,6,6-tetramethyl-4-piperidinyl)imino]-1,6 hexanediyl[(2,2,6,6-tetramethyl-4-piperidinyl)imino]]) (Chimasorb 944FD or Sabostab UV94/=HALS). The hindered amine light stabilizer may for example be present in an amount of ≥0.05 wt. % and ≤5.0 wt. % with regard to the total weight of the polyolefin composition.

The coupling agent and the one or more additives may be present in a suitable amount such that each of the coupling agent and the one or more additives is present in an amount of ≥0.05 wt. % and ≤5.0 wt. %, with regard to the total weight of the polyolefin composition.

Preferably, the polyolefin composition comprises:
a) ≥0.05 wt. % and ≤5.0 wt. %, of a coupling agent; and
b) ≥0.05 wt. % and ≤5.0 wt. % of one or more additives;
   with regard to the total weight of the polyolefin composition, wherein the one or more additives is selected from anti-oxidants, heat stabilizers, acid scavengers, release agents, plasticizers, hindered amine light stabilizer, antistatic additive, non-phenolic processing stabilizer, lubricants, anti-statics, scratch resistance agents, recycling additives, clarifying agent, processing stabilizers, antimicrobial agents, anti-fogging additives, slip additives, anti-blocking additives, non-phenolic processing stabilizer, or combinations thereof.

In some preferred embodiments of the invention, the composition comprises:
a) ≥60.0 wt. % and ≤99.0 wt. % of the ethylene alpha-olefin co-polymer;
b) ≥1.0 wt. % and ≤35.0 wt. % of the ethylene-alpha-olefin-diene terpolymer;
c) ≥0.1 wt. % and ≤5.0 wt. % of the crosslinking agent;
d) ≥0.05 wt. % and ≤5.0 wt. %, of the coupling agent; and
e) ≥0.05 wt. % and ≤5.0 wt. % of one or more additives;
   with regard to the total weight of the polyolefin composition.

Accordingly, the polyolefin composition has a unique set of properties, which render the composition to be useful for use as encapsulants for solar cells and other electronic modules. For example, the polyolefin composition may have has at least one of:
a) volume resistivity (VR) of >1.0×10¹⁵ Ω·cm, preferably the polyolefin composition has a volume resistivity (VR) of >1.0×10¹⁵ Ω·cm and <2.0×10¹⁸ Ω·cm, preferably >1.0×10¹⁶ Ω·cm and <1.0×10¹⁷ Ω·cm, when determined in accordance with ASTM D257-14 (2021) at an applied voltage of 1000V for a time period of 600 seconds and at a temperature of 25° C.;
b) a peak melting temperature of ≥60° C. and ≤75° C., preferably ≥65° C. and ≤72° C., when determined in accordance with ASTM D3418-15, using Differential Scanning calorimetry (DSC) with a first heating and cooling cycle at a temperature between 23° C. to 200° C. and at a heating and a cooling rate of 10° C./min for a 10 mg film sample, using a nitrogen purge gas at flow rate of 50±5 mL/min, followed by a second heating cycle identical to the first heating cycle;
c) a density of ≥850 kg/m³ and ≤880 kg/m³, when determined in accordance with ASTM D792 (2008);
d) a beta conversion (β) for crosslinking of ≥0.4 and ≤0.7 at a time period of 1000 seconds, wherein the beta conversion for crosslinking is determined by using the formula:
   Beta conversion (β)=(G′(1000)−G′(0))/(G′(5000)−G′(0)), wherein G′(1000) is the storage modulus of the polyolefin composition at time 1000 seconds, G′(0) is the storage modulus of the polyolefin composition at time 0 seconds, G′(5000) is the storage modulus of the polyolefin composition at time 5000 seconds, wherein the storage modulus is determined in accordance with ISO 6721-10 at a temperature of 150° C. under a nitrogen environment using a parallel plate set-up at a frequency of 6.28 radian/sec, and at an oscillation strain of 0.1%;
e) a tensile modulus of ≥11.0 MPa and ≤25.0 MPa, when determined in accordance with ASTM D882 (2018);
f) a tensile strength @ break of ≥10.5 MPa and ≤25.0 MPa, when determined in accordance with ASTM D882 (2018);
g) a Durometer Hardness (Shore Hardness D) of ≥19.0, when determined in accordance with ASTM D2240-15 (2021).

Preferably, the polyolefin composition has at least one of:
a) volume resistivity (VR) of >1.0×10¹⁵ Ω·cm, preferably the polyolefin composition has a volume resistivity (VR) of >1.0×10¹⁵ Ω·cm and <2.0×10¹⁸ Ω·cm, preferably >1.0×10¹⁶ Ω·cm and <1.0×10¹⁷ Ω·cm, when determined in accordance with ASTM D257-14 (2021) at an applied voltage of 1000V for a time period of 600 seconds and at a temperature of 25° C.;
b) a peak melting temperature of ≥60° C. and ≤75° C., preferably ≥65° C. and ≤72° C., when determined in accordance with ASTM D3418-15, using Differential Scanning calorimetry (DSC) with a first heating and cooling cycle at a temperature between 23° C. to 200° C. and at a heating and a cooling rate of 10° C./min for a 10 mg film sample, using a nitrogen purge gas at flow rate of 50±5 mL/min, followed by a second heating cycle identical to the first heating cycle;
c) a density of ≥850 kg/m³ and ≤880 kg/m³, when determined in accordance with ASTM D792 (2008);
d) a beta conversion (β) for crosslinking of ≥0.4 and ≤0.7 at a time period of 1000 seconds, wherein the beta conversion for crosslinking is determined by using the formula:
   Beta conversion (β)=(G′(1000)−G′(0))/(G′(5000)−G′(0)), wherein G′(1000) is the storage modulus of the polyolefin composition at time 1000 seconds, G′(0) is the storage modulus of the polyolefin composition at time 0 seconds, G′(5000) is the storage modulus of the polyolefin composition at time 5000 seconds, wherein the storage modulus is determined in accordance with ISO 6721-10 at a temperature of 150° C. under a nitrogen environment using a parallel plate set-up at a frequency of 6.28 radian/sec, and at an oscillation strain of 0.1%;
e) a tensile modulus of ≥11.0 MPa and ≤25.0 MPa, when determined in accordance with ASTM D882 (2018);
f) a tensile strength @ break of ≥10.5 MPa and ≤25.0 MPa, when determined in accordance with ASTM D882 (2018);
g) a Durometer Hardness (Shore Hardness D) of ≥19.0, when determined in accordance with ASTM D2240-15 (2021).

In particular, the polyolefin composition has a suitable curing time, enabling the composition to be cross-linked at a relatively short duration of time. A convenient proxy for determining the ease of cross-linking is by determining the Beta conversion. In other words, beta conversion represents the extent of cross-linking at a particular time period, for example 1000 seconds, after the initiation of the cross-linking reaction. For the purpose of calculation, the time period of 5000 seconds is taken to represent a sufficiently long time period (an infinite time period from the initiation of the process) under which a certain degree of cross-linking reaction, for example >60%, preferably >80%, more preferably >85%, has been achieved. Preferably, the polyolefin composition has a volume resistivity (VR) of >1.0×10¹⁵ Ω·cm and <2.0×10¹⁸ Ω·cm, preferably >1.0×10¹⁶ Ω·cm and <1.0×10¹⁷ Ω·cm and a beta conversion (β) for crosslinking at 150° C. of ≥0.4 and ≤0.7, at a time period of 1000 seconds, indicating that the polyolefin composition is able to retain high volume resistivity even while having fast cross-linking properties.

In some preferred embodiments of the invention, the invention is directed to a process for preparing the polyolefin composition, wherein the process comprises the steps of:
a) providing to an extruder a set of ingredients comprising an ethylene alpha-olefin co-polymer, an ethylene-alpha-olefin-diene terpolymer, a crosslinking agent, optionally a coupling agent, and optionally one or more additives; and
b) extruding the set of ingredients at a melt temperature of ≤100° C. and forming the composition.

Preferably, in some embodiments of the invention, the set of ingredients comprises an ethylene alpha-olefin co-polymer, an ethylene-alpha-olefin-diene terpolymer, a crosslinking agent, a silane coupling agent, and one or more additives. Preferably, the ingredients are extruded at a melt temperature of ≥55° C. and ≤100° C., preferably at a melt temperature of ≥60° C. and ≤80° C., and forming the composition. The ingredients may be dry blended to form a blended mixture outside the extruder and subsequently the blended mixture may be introduced inside the extruder via the hoper of the extruder. Alternatively, the set of ingredients may be introduced individually into the extruder via the hopper such that the ingredients are blended inside the extruder prior to being extruded.

In some preferred embodiments of the invention, the invention is directed to a film comprising or consisting of the polyolefin composition of the present invention. The film may be prepared by a process, comprising the steps of:
a) providing to an extruder a set of ingredients comprising an ethylene alpha-olefin co-polymer, an ethylene-alpha-olefin-diene terpolymer, a crosslinking agent, optionally a coupling agent, and optionally one or more additives;
b) extruding the set of ingredients at a melt temperature of ≤100° C. and forming an extrudate;
c) casting the extrudate at a temperature of ≤100° C. and forming the film.

In some embodiments of the invention, the set of ingredients comprises an ethylene alpha-olefin co-polymer, an ethylene-alpha-olefin-diene terpolymer, a crosslinking agent, a silane coupling agent, and one or more additives. Preferably, during the film production, the ingredients are extruded at a melt temperature of ≥55° C. and ≤100° C., preferably at a melt temperature of ≥60° C. and ≤80° C., and forming the extrudate. The extrudate may be further casted to form the film. The casting of the film may be carried out at any suitable temperature of ≥70° C. and ≤100° C. In some embodiments of the invention, the film so obtained may be further heated and subsequently stretched to form an oriented film, for example a bi-directionally oriented film.

The film, once formed, may be used for preparing sealing layers suitable to be used in photovoltaic modules or other electronic modules. For example, in some embodiments of the invention, the invention is directed to an encapsulated solar cell comprising a solar cell positioned between a first sealing layer and a second sealing layer, wherein each of the first sealing layer and the second sealing layer comprise or consist of the film of the present invention, wherein the solar cell may be positioned such that the first sealing layer and the second sealing layer are joined so as to completely encapsulate the solar cell. The film may have a suitable thickness. For example, the film has a cross-sectional thickness of ≥200 μm and ≤800 μm, preferably ≥300 μm and ≤500 μm.

Solar cell used for the context of the present invention are known to a person skilled in the art. For example, the solar cell may be any standard commercially available crystalline or amorphous silicon solar cell or CIGS (copper indium gallium selenide) thin film. The person skilled in the art will know what type of electrical connection to use, for example electrical conductors may be metal strips such as strips comprising copper aluminum and/or silver or, in the alternative, may be metal wires.

The encapsulated solar cell may be subjected to further processing for example, curing to render the encapsulated solar cell suitable to be used in photovoltaic module. For example, in some embodiments of the invention, the invention is directed to a cured solar cell obtained by subjecting the encapsulated solar cell under conditions sufficient to cure the first sealing layer and the second sealing layer.

The cured solar cell may be prepared by a process comprising the steps of:
(a) providing the first sealing layer, the second sealing layer, and the solar cell;
(b) assembling the first sealing layer, the solar cell, and the second sealing layer and forming the encapsulated solar cell;
(c) curing the encapsulated solar cell under conditions sufficient to cure the first sealing layer and the second sealing layer to form the cured solar cell.

The expression “curing” as used herein means crosslinking the various components of the polyolefin composition under heat or radiation or chemically. Preferably, crosslinking can be effected by any one of a number of different methods as known to the person skilled in the art, e.g., by the use of thermally activated initiators, e.g., peroxides and azo compounds; photoinitiators, e.g., benzophenone; radiation techniques including sunlight, UV light, E-beam and x-ray; silane, e.g., vinyl tri-ethoxy or vinyl tri-methoxy silane; and moisture curing. Preferably the crosslinking is carried out using organic peroxides. The expression “cured solar cell” as used herein means the solar cell encapsulated in a sealing layer, where the sealing layers have been cured under conditions sufficient to induce crosslinking within the sealing layers.

Preferably, the curing process is carried out by heating. The curing step under heat may for example be carried out at any temperature of ≥135° C. and ≤150° C., preferably ≥140° C. and ≤145° C. The curing step may for example be carried out for a time period of ≤1 hour, preferably ≤30 minutes, preferably ≤20 minutes and ≥3 minutes. Advantageously, sealing layers are composed of a film having a polyethylene composition, which enables curing at a relatively short time period while retaining sufficiently high volume resistivity.

Accordingly, in some embodiments of the invention, the invention is directed to the use of the polyolefin composition or the film, for the reduction of cross-linking time during the production of a photovoltaic module.

For example, the cured solar cell once formed may be integrated with various components of a photovoltaic module. Preferably, in some embodiments of the invention, the invention is directed to a photovoltaic module comprising the cured solar cell of the present invention. Preferably such a photovoltaic module may comprise:
a) a front protection member;
b) a back protection member;
c) the cured solar cell, wherein the cured solar cell is positioned between the front protection member and the back protection member.

Preferably, the invention relates to a photovoltaic module comprising the cured solar cell of the present invention, preferably wherein the photovoltaic module comprises:
a) a front protection member;
b) a back protection member;
c) the cured solar cell, wherein the cured solar cell is positioned between the front protection member and the back protection member.

The front and the back protection member may be prepared of suitable material, for example polypropylene materials. The photovoltaic module may for example be prepared by positioning the cured solar cell between the front protection member and the back protection member followed by thermal treatment to laminate the cured solar cell between the front protection member and the back protection member.

Alternatively, the cured solar cell may be produced in-situ during the production of the photovoltaic module itself. For example, in some embodiments of the invention the photovoltaic module is prepared by a process involving:
(a) assembling the front protection member, the first sealing layer, the second sealing layer, the solar cell and the back protection member to form a photovoltaic assembly having i) the encapsulated solar cell comprising the solar cell positioned between the first sealing layer and the second sealing layer, ii) the first sealing layer is in contact with the front protection member; and iii) the second sealing layer is in contact with the back protection layer;
(b) subjecting the photovoltaic assembly under conditions of pressure and heat such that at least part of the sealing layers melt to form a laminated photovoltaic assembly;
(c) subjecting the laminated photovoltaic assembly to conditions of curing to form the photovoltaic module comprising the cured solar cell.

In some embodiments of the invention, the assembling step involves a specific order of assembling the various components of a photovoltaic module to form the photovoltaic assembly. The steps to prepare such a photovoltaic assembly may involve:
a) providing the back protection member;
b) positioning the second sealing layer on the back protection member such that the second sealing layer is in contact with the back protection member;
c) positioning the solar cell on the second sealing layer such that the second sealing layer is positioned between the solar cell and the back protection member;
d) positioning the first sealing layer on the solar cell such that the solar cell is positioned between the first sealing layer and the second sealing layer;
e) positioning the front protection member on the first sealing layer such that the first sealing layer is positioned between the front protection member and the solar cell;
f) subjecting the above assembly to a further set of processing steps including curing, to form the photovoltaic module.

Optionally, the laminated assembly post curing may be cooled prior to forming the photovoltaic module. Preferably during the heating step, the assembly is heated to a temperature such that the front protection member and the back protection member do not melt. For example the temperature of this heating step may be so chosen such that the front protection member attains a temperature of at least 5° C. below the melting temperature of the front layer. In practice, the temperature of the heating step is chosen as high as possible to enable a maximum adherence between the sealing layers and the protection layers, while at the same time the temperature, is not too high, so that the front and back layers remain solid.

Specific examples demonstrating some of the embodiments of the invention are included below. The examples are for illustrative purposes only and are not intended to limit the invention. It should be understood that the embodiments and the aspects disclosed herein are not mutually exclusive and such aspects and embodiments can be combined in any way. Those of ordinary skill in the art will readily recognize parameters that can be changed or modified to yield essentially the same results.

### EXAMPLES

Purpose: For the purposes of exemplifying the present invention, four inventive formulations (IE1-IE3) were prepared and its properties were compared with that of comparative formulations (CE1). The details of the formulations are provided below:

TABLE 1

| | Grade Name | IE1 | | IE2 | | IE3 | | CE1 | |
|---|---|---|---|---|---|---|---|---|---|
| Ethylene alpha- | C13075DP | 94.0 | wt. % | 89.0 | wt. % | 79 | wt. % | 99 | wt. % |
| olefin co-polymer | (SABIC) | | | | | | | | |
| (POE) wt. % | | | | | | | | | |
| Ethylene-alpha- | NORDEL ™ IP | 5.0 | wt. % | 10.0 | wt. % | 20 | wt. % | 0 | wt. % |
| olefin-diene | 3720P | | | | | | | | |
| terpolymer | | | | | | | | | |
| (EPDM) | | | | | | | | | |
| wt. % | | | | | | | | | |
| Crosslinking | Luperox ® | 1.0 | wt. % | 1.0 | wt. % | 1.0 | wt. % | 1.0 | wt. % |

| | |
|---|---|
| agent: | DCP |
| Dicumylperoxide | |
| wt. % | |

Method of preparation: The above formulations of weight (˜50 g) were prepared by dry blending C13075DP, EPDM 3720 and peroxide DCP in a twin screw extruder. The blend was subsequently extruded below 100° C. at a 15 kg/h output to obtain the samples. The samples obtained were further casted at single screw line at 90° C. to make an encapsulant sheet with a thickness of 400 μm. The samples obtained were further subjected to a cross-linking or curing condition at 150° C.

Testing: For measuring beta conversion, the storage modulus was determined in accordance with ISO 6721-10. Rheology measurements were carried out using an ARES-G2 rheometer using 25 mm parallel plates at temperatures of 150° C. The frequency sweep was carried out at a frequency of 6.28 radian/sec and at an oscillation strain of 0.1%. For determining beta conversion, the storage modulus across a time period post the initiation of cross-linking was determined at a time period ranging from zero seconds to 5000 seconds.

The volume resistivity may be determined in accordance with ASTM D257-14 (2021), at an applied voltage of 1000V for a time period of 600 seconds and at a temperature of 25° C.

The results from the test analysis are provided below.

TABLE 2

| | | | | | 100% |
|---|---|---|---|---|---|
| | IE1 | IE2 | IE3 | CE1 | EPDM |
| Beta conversion | 0.406 | 0.431 | 0.455 | 0.385 | — |
| at 1000 seconds | | | | | |
| measured at 150° C. | | | | | |
| Volume resistivity | 2.1 × | 1.6 × | 8.5 × | 3.9 × | 1.4 × |
| Ω · cm | 10¹⁶ | 10¹⁶ | 10¹⁵ | 10¹⁶ | 10¹⁵ |

From the data provided in Table 2, it is evident that with increase in EPDM concentration present in the inventive polyolefin composition (IE1-IE3), the cross-linking time is reduced as indicated by the higher beta conversion value (e.g. IE3 versus CE3). Advantageously the inventive polyolefin compositions are able to retain sufficiently high volume resistivity, rendering such compositions to be suitable for application in the manufacture of photovoltaic modules.

1. A polyolefin composition, comprising:
a) ≥60.0 wt. % and ≤99.0 wt. % of an ethylene alpha-olefin co-polymer, with regard to the total weight of the polyolefin composition;
wherein the ethylene alpha-olefin co-polymer has at least one of:
i. a peak melting temperature of ≥60° C. and ≤90° C., when determined in accordance with ASTM D3418-15, using Differential Scanning calorimetry (DSC) with a first heating and cooling cycle at a temperature between 23° C. to 200° C. and at a heating and a cooling rate of 10° C./min for a 10 mg film sample, using a nitrogen purge gas at flow rate of 50±5 mL/min, followed by a second heating cycle identical to the first heating cycle;
ii. ≥20.0 wt. % and ≤45.0 wt. %, of polymeric units derived from one or more alpha-olefins having 3-12 carbon atoms, with regard to the total weight of the ethylene alpha-olefin co-polymer; or
iii. a vinyl unsaturation of ≥6.0 per 10⁵ carbon atoms, when determined in accordance with ASTM D6248-98 (2012);
b) ≥1.0 wt. % and ≤35.0 wt. % of an ethylene-alpha-olefin-diene terpolymer, with regard to the total weight of the polyolefin composition, wherein the ethylene-alpha-olefin-diene terpolymer comprises a total vinyl and vinylidene unsaturation of ≥20.0 and ≤100.0 per 10⁵ carbon atoms, when determined in accordance with ASTM D6248-98 (2012); and
c) ≥0.1 wt. % and ≤5.0 wt. % of a crosslinking agent, with regard to the total weight of the polyolefin composition.

2. The polyolefin composition according to claim 1, wherein the ethylene alpha-olefin co-polymer has at least one of:
a) a melt flow rate (MFR) of ≥5.0 g/10 min and ≤25.0 g/10 min, when determined at 190° C. at 2.16 kg load in accordance with ASTM D1238 (2013); and/or
b) a density of ≥850 kg/m³ and ≤900 kg/m³, when determined in accordance with ASTM D792 (2008).

3. The polyolefin composition according to claim 1, wherein the ethylene alpha-olefin co-polymer comprises the ethylene-alpha-olefin-diene terpolymer, and the ethylene-alpha-olefin-diene terpolymer comprises polymeric units derived from (i) ethylene; (ii) one or more alpha-olefins comprising 3-12 carbon atoms; and (iii) a diene selected from the group consisting of 5-ethylidene-2-norbornene, 5-propylidene-5-norbornene, dicyclopentadiene, 5-vinyl-2-norbornene, 5-methylene-2-norbornene, 5-isopropylidene-2-norbornene, norbornadiene, 1,4-hexadiene, 4-methyl-1,4-hexadiene, 5-methyl-1,4-hexadiene, 5-methyl-1,5-heptadiene, 6-methyl-1,5-heptadiene, 6-methyl-1,7-octadiene, 1,6-octadiene, 5-methyl-1,4-hexadiene, 3,7-dimethyl-1,6-octadiene, 2,5-norbornadiene and 7-methyl-1,6-octadiene.

4. The polyolefin composition according to claim 1, wherein the crosslinking agent is an organic peroxide selected from the group consisting of 2,5-dimethyl-2,5-di(t-butylperoxy)hexane, 3-di-t-butylperoxide, t-dicumylperoxide, 2,5-dimethyl-2,5-di(t-butylperoxy)hexyne, dicumylperoxide, α,α′-bis(t-butylperoxyisopropyl)benzene, n-butyl-4,4-bis(t-butylperoxy)butane, 2,2-di(tert-butylperoxy)butane, 1,1-bis(t-butylperoxy)cyclohexane, tertiarybutylperoxy-2-ethylhexyl carbonate, t-butylperoxybenzoate, 1,6-di(t-butylperoxycarbonyloxy)hexane, and combinations thereof.

5. The polyolefin composition according to claim 1, wherein the polyolefin composition, further comprises:
a) ≥0.05 wt. % and ≤5.0 wt. %, of a coupling agent; and
b) ≥0.05 wt. % and ≤5.0 wt. % of one or more additives;
with regard to the total weight of the polyolefin composition, wherein the one or more additives is selected from anti-oxidants, heat stabilizers, acid scavengers, release agents, plasticizers, hindered amine light stabilizer, antistatic additive, non-phenolic processing stabilizer, lubricants, anti-statics, scratch resistance agents, recycling additives, clarifying agent, processing stabilizers, antimicrobial agents, anti-fogging additives, slip additives, anti-blocking additives, non-phenolic processing stabilizer, or combinations thereof.

6. The polyolefin composition according to claim 5, wherein the composition comprises:
a) ≥60.0 wt. % and ≤99.0 wt. % of the ethylene alpha-olefin co-polymer;
b) ≥1.0 wt. % and ≤35.0 wt. % of the ethylene-alpha-olefin-diene terpolymer;
c) ≥0.1 wt. % and ≤5.0 wt. % of the crosslinking agent;
d) ≥0.05 wt. % and ≤5.0 wt. %, of the coupling agent; and
e) ≥0.05 wt. % and ≤5.0 wt. % of one or more additives;
with regard to the total weight of the polyolefin composition.

7. The polyolefin composition according to claim 1, wherein the polyolefin composition has at least one of:
a) volume resistivity of >1.0×10¹⁵ Ω·cm, when determined in accordance with ASTM D257-14 (2021) at an applied voltage of 1000V for a time period of 600 seconds and at a temperature of 25° C.;
b) a peak melting temperature of ≥60° C. and ≤75° C., when determined in accordance with ASTM D3418-15, using Differential Scanning calorimetry (DSC) with a first heating and cooling cycle at a temperature between 23° C. to 200° C. and at a heating and a cooling rate of 10° C./min for a 10 mg film sample, using a nitrogen purge gas at flow rate of 50±5 mL/min, followed by a second heating cycle identical to the first heating cycle;
c) a density of ≥850 kg/m³ and ≤880 kg/m³, when determined in accordance with ASTM D792 (2008);
d) a beta conversion (β) for crosslinking at 150° C. of ≥0.4 and ≤0.7 at a time period of 1000 seconds, wherein the beta conversion for crosslinking is determined by using the formula:
Beta conversion (β)=(G′(1000)−G′(0))/(G′(5000)−G′(0)), wherein G′(1000) is the storage modulus of the polyolefin composition at time 1000 seconds, G′(0) is the storage modulus of polyolefin composition at time 0 seconds, G′(5000) is the storage modulus of the polyolefin composition at time 5000 seconds, wherein the storage modulus is determined in accordance with ISO 6721-10 at a temperature of 150° C. under a nitrogen environment using a parallel plate set-up at a frequency of 6.28 radian/sec, and at an oscillation strain of 0.1%;
e) a tensile modulus of ≥11.0 MPa and ≤25.0 MPa, when determined in accordance with ASTM D882 (2018);
f) a tensile strength @ break of ≥10.5 MPa and ≤25.0 MPa, when determined in accordance with ASTM D882 (2018); or
g) a Durometer Hardness (Shore Hardness D) of ≥19.0, when determined in accordance with ASTM D2240-15 (2021).

8. A process for preparing the polyolefin composition according to claim 1, wherein the process comprises the steps of:
a) providing to an extruder a set of ingredients comprising an ethylene alpha-olefin co-polymer, an ethylene-alpha-olefin-diene terpolymer, a crosslinking agent, optionally a coupling agent, and optionally one or more additives; and
b) extruding the set of ingredients at a melt temperature of ≤100° C. and forming the composition.

9. A film comprising or consisting of the polyolefin composition according to claim 1.

10. A process for preparing the film of claim 9, wherein the process comprises the steps of:
a) providing to an extruder a set of ingredients comprising an ethylene alpha-olefin co-polymer, an ethylene-alpha-olefin-diene terpolymer, a crosslinking agent, optionally a coupling agent, and optionally one or more additives;
b) extruding the set of ingredients at a melt temperature of ≤100° C. and forming an extrudate; and
c) casting the extrudate at a temperature of ≤100° C. and forming the film.

11. An encapsulated solar cell comprising a solar cell positioned between a first sealing layer and a second sealing layer, wherein each of the first sealing layer and the second sealing layer comprises the film of claim 9, wherein the solar cell is positioned such that the first sealing layer and the second sealing layer are joined so as to completely encapsulate the solar cell.

12. A cured solar cell obtained by subjecting the encapsulated solar cell of claim 11 under conditions sufficient to cure the first sealing layer and the second sealing layer.

13. A process comprising the steps of:
(a) providing the first sealing layer, the second sealing layer, and the solar cell of claim 11;
(b) assembling the first sealing layer, the solar cell, and the second sealing layer and forming the encapsulated solar cell; and
(c) curing the encapsulated solar cell under conditions sufficient to cure the first sealing layer and the second sealing layer to form the cured solar cell.

14. A photovoltaic module comprising the cured solar cell according to claim 12, wherein the photovoltaic module comprises:
a) a front protection member;
b) a back protection member;
c) the cured solar cell, wherein the cured solar cell is positioned between the front protection member and the back protection member.

15. (canceled)

16. The polyolefin composition of claim 1, wherein the ethylene alpha-olefin co-polymer comprises polymeric units derived from ethylene and one or more alpha-olefin selected from 1-butene, 1-hexene, 4-methyl-1-pentene, 1-octene, or combinations thereof.

17. The polyolefin composition of claim 16, wherein the alpha-olefin is selected from 1-butene or 1-octene.

18. The polyolefin composition of claim 3, wherein the ethylene-alpha-olefin-diene terpolymer is ethylene/propylene/5-ethylidene-2-norbornene copolymer.

19. The polyolefin composition of claim 4, wherein the crosslinking agent is dicumylperoxide.
